(19) United States
(12) Patent Application Publication
(10) Pub. No.: US 2005/0048724 A1
(43) Pub. Date: Mar. 3, 2005

(54) Deep submicron manufacturing method for electrostatic discharge protection devices

(76) Inventor: Jung-Cheng Kao, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/922,837

(22) Filed: Aug. 23, 2004

(30) Foreign Application Priority Data
Sep. 1, 2003 (CN) 03150709.3

(51) Int. Cl. H01L 21/8238; H01L 21/8234

(52) U.S. Cl. 438/275; 438/200; 438/231

(57) ABSTRACT

The present invention provides a manufacturing method of an electrostatic discharge protection device for deep submicron manufacturing processing. In deep submicron manufacturing processing, non-uniform high current causes the electrostatic protection components to be broken while the self-aligned salicide is applied to source/drain region of transistors which include electrostatic discharge (ESD) protection components. For improving the problem, the present invention forms no self-aligned salicide in the electrostatic discharge protection components region but a resistance ballast is formed between the drain contact and the poly gate by utilizing a self-aligned salicide block. It renders the high current generated from electrostatic discharge capable of discharging in a homogeneous manner in order to avoid the electrostatic protection components from being damaged.

### FIELD OF THE INVENTION

The present invention relates to a manufacturing method of an ESD protection device, and more particularly to a manufacturing method applying self-aligned salicide to an ESD protection device for deep submicron manufacturing processing and meanwhile prevents the electrostatic discharge structure from being damaged.

### BACKGROUND OF THE INVENTION

The structures of NMOS or PMOS (N/P MOS) transistors, for examples, gg (gate ground) N/P MOS, gc (gate-control) N/P MOS components or other type structures, are applied generally to deep submicron ESD protection device components nowadays. An N/P MOS parasitic bipolar transistor is triggered and guides the high current generated from its high voltage to Vss or Vdd when momentary high voltage occurs because of its component characteristic of parasitic bipolar transistors.

FIG. 1 shows a circuit structure of a gg N/P MOS component applied to integrated circuit to be ESD protection device 10. The momentary high voltage turns on the NMOS parasitic bipolar component 12 for guiding high current to Vss and the momentary reverse high voltage turns on the PMOS parasitic bipolar component 14 for guiding high current to Vdd. The applied theorem shows in FIG. 2. When an electrostatic discharge event occurs at an input pad, the gg N/P MOS will be triggered and enters a snapback region. The gg N/P MOS will clamp a low potential voltage across itself and remain a high current. It renders the electrostatic discharge current to be guided out efficiently.

When gg N/P MOS components are applied to structures of ESD protection devices which are manufactured by non-self-aligned salicide manufacturing processes, a buffer distance between its drain contact 16 and poly gate 18 becomes a resistance ballast. It renders the high current to be homogenous discharged when the NPN transistor 20 is triggered.

However, in deep submicron manufacturing processing, the self-aligned salicide applied to poly gate 18 and source/drain region 24, 16 which includes electrostatic discharge (ESD) protection components as shown in FIG. 4, renders the region between the drain contact 16 and the poly gate 18 without any resistance ballast. When an electrostatic high voltage generates for triggering the NPN (or PNP) transistor in the ESD protection device structure, although the current generated from high voltage can be discharged, the collector N (as the drain of gg NMOS) of the NPN transistor has no resistance ballast and it's a shallow junction structure. This renders the high current flow inhomogeneously and causes local high current and local heating effect generated exists near the drain to break the ESD protection structure latency and furthermore lose the effect of ESD protection.

According to the disadvantages above, the present invention provides a manufacturing method of a electrostatic discharge protection device for deep submicron manufacturing processing to solve the above-mentioned problems.

### SUMMARY OF THE INVENTION

An object of the present invention is to provide a manufacturing method of an electrostatic discharge protection device for deep submicron manufacturing processing. It utilizes a manner of a self-aligned salicide block on the ESD protection structure under manufacturing the self-aligned salicide in order to avoid undesired self-aligned salicide generated between the drain contact and the poly gate of the ESD protection structure and thereby provides a resistance ballast to discharge the high current generated from electrostatic discharge in a homogeneous manner.

Another object of the present invention is to provide a manufacturing method of electrostatic discharge protection device for deep submicron manufacturing processing which guides out the high current generated from electrostatic high voltage effectively in order to avoid local high current and local heating effect generated to exist near the drain and prevents the ESD protection structure from being broken.

In order to achieve the objects above, the present invention at first forms basic components of block structures, doping-wells, poly gate structures, light ion doping regions and heavy doping regions to be source/drain on a semiconductor substrate; and then forms a thin layer and a patterned photoresist on the semiconductor substrate, and uses the patterned photoresist as a mask and etches for removing said thin layer on non-ESD protection component region of said semiconductor substrate. The remnant thin layer only covers on the ESD protection component region of the semiconductor substrate, then the patterned photoresist is removed. Next, the remnant thin layer is removed when completed forming self-aligned salicide on the surface of the poly gate, source/drain region on the non-ESD protection component region of the semiconductor substrate.

The foregoing and other objects, features and advantages of the invention will be apparent from the following more particular description of preferred embodiments with reference to the accompanying diagrammatic drawings of the invention.

### BRIEF DESCRIPTION OF THE DRAWINGS

FIG. 1 illustrates a circuit structure diagram of MOS components applied to integrated circuit of conventional ESD protection devices;

FIG. 2 illustrates a curve of electrostatic discharge occurring;

FIG. 3 illustrates a structure diagram of conventional MOS components applied to ESD protection devices;

FIG. 4 illustrates a transistor structure diagram of conventional ESD protection devices with self-aligned salicide; and

FIG. 5(a) to FIG. 5(e) illustrate structure cross-section views of each step of manufacturing internal circuit and ESD protection device of preferred embodiments of the present invention.

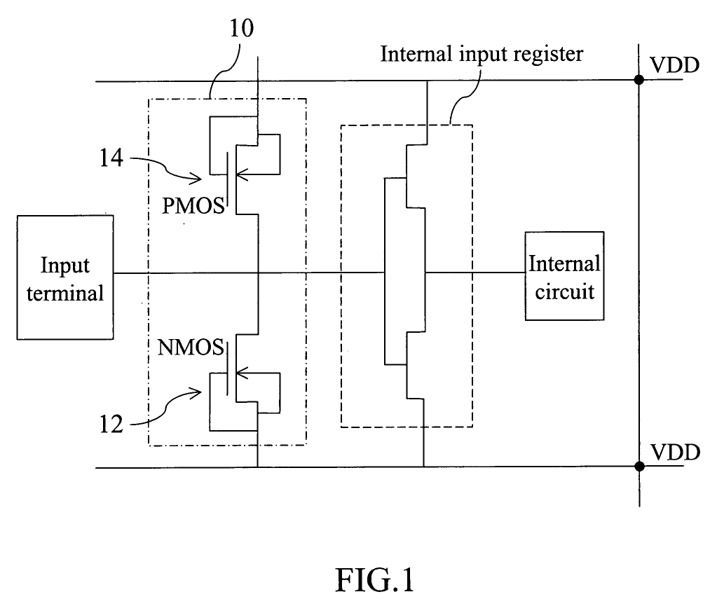

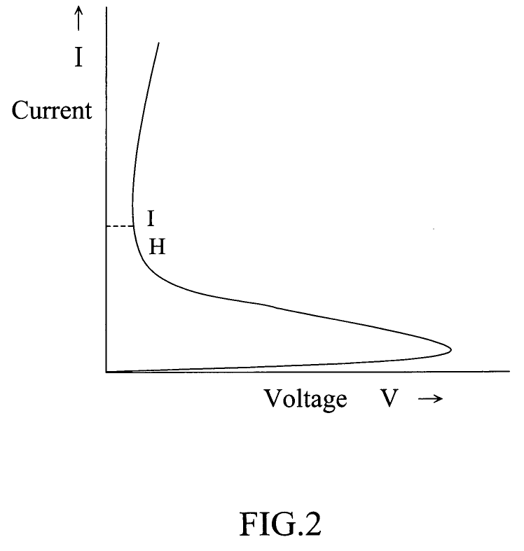

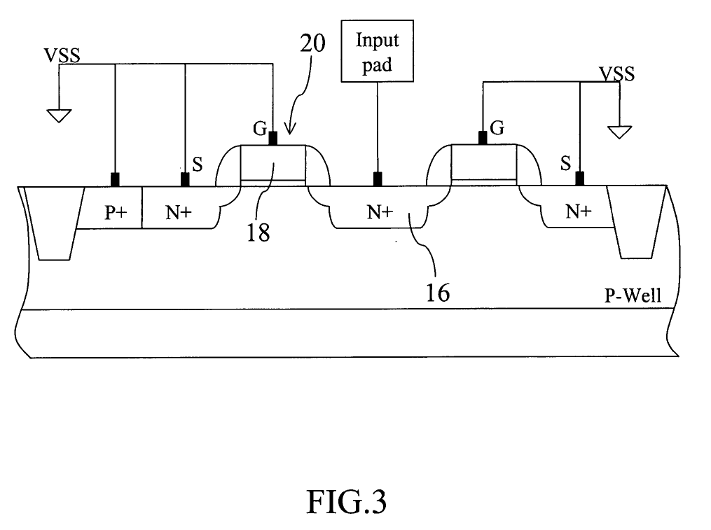

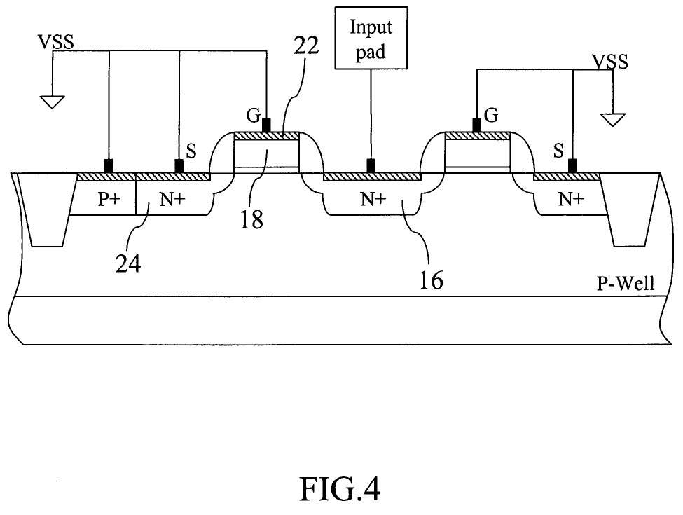

### DETAILED DESCRIPTION OF THE PREFERRED EMBODIMENTS

The present invention improves the disadvantages which generate from ESD protection components in self-aligned salicide manufacturing processes. It uses the manner of a self-aligned salicide block for forming no salicide on the poly gate and source/drain region in ESD protection components region and renders a resistance ballast between the drain contact and poly gate to discharge the high current generated from electrostatic discharge in a homogeneous manner without forming local high current and local heating effect near the drain.

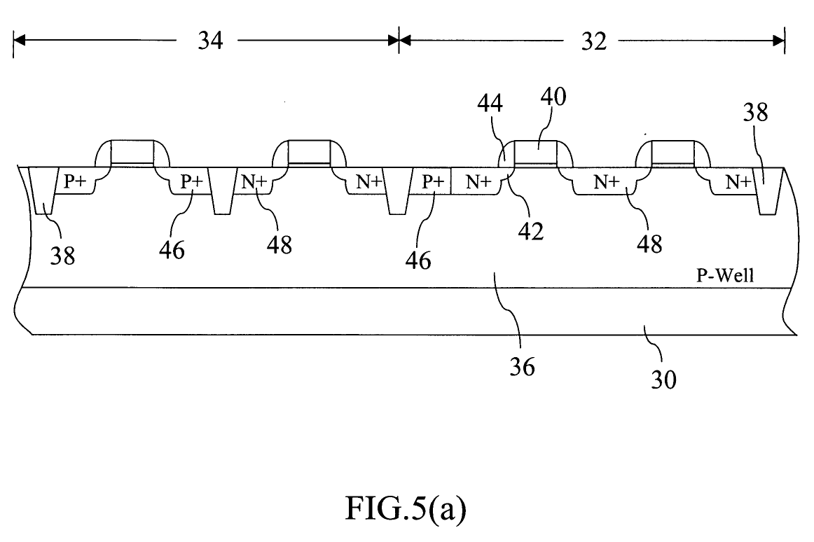

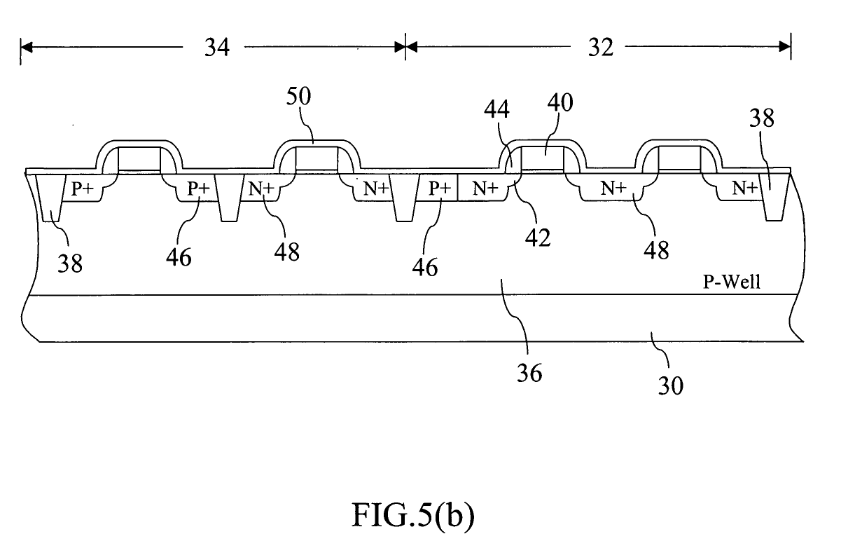

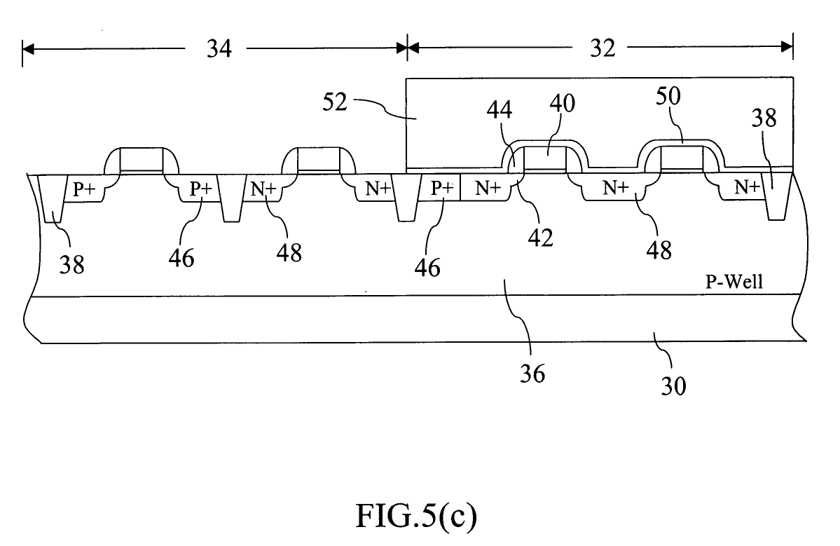

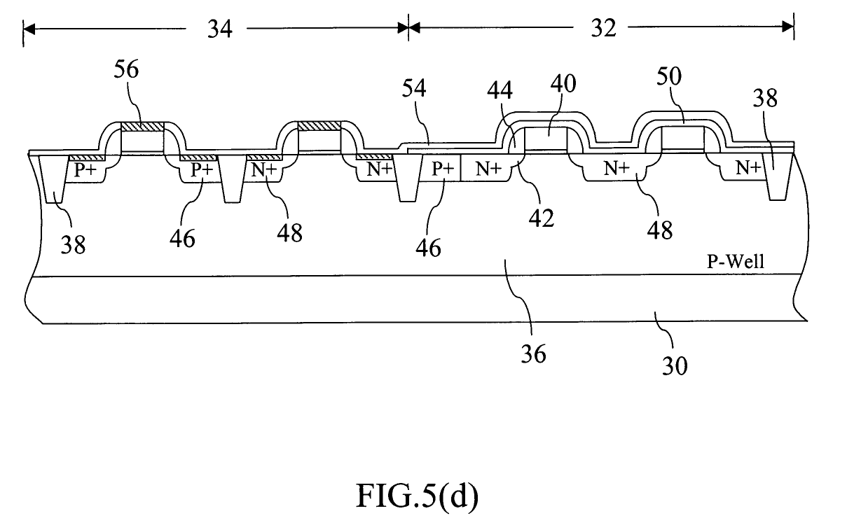

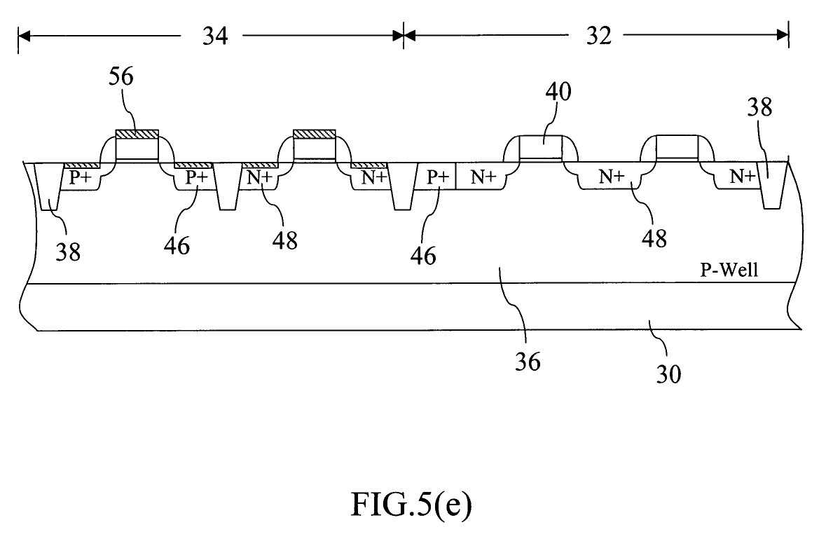

FIG. 5(a) to FIG. 5(e) illustrate cross-section views of each step of manufacturing transistors' internal circuit and ESD protection device of preferred embodiments of the present invention. They utilize NMOS transistors as examples to give a full detail of the manufacturing process of the present invention.

Referring to FIG. 5(a), there is an ESD protection component region 32 and an internal circuit region 34 of non-ESD protection component region on a semiconductor substrate 30. At first, a deep submicron standard manufacturing process is carried out. A P-well 36 is formed by carrying out ion doping in the semiconductor substrate 30 and multiple shallow trench isolation (STI) regions are formed in p-wells. A plurality of poly gate structures 40 are formed on the semiconductor substrate, and the gate structures 40 are used as a mask to carry out a low concentration ion implantation to the P-well for forming light ion doping regions. Gate spacers 44 are formed beside two sidewalls of the gate structures 40. The gate structures 40 and the gate spacers are masked to carry out a high concentration P-type and N-type heavy ion implantation for forming P-type heavy ion doping regions 46 and N-type heavy ion doping regions 48 respectively to be source/drain regions. A rapid thermal anneal process is then carried out. Hereunto, said basic components on the semiconductor substrate 30 have been manufactured.

Referring to FIG. 5(b), a thin oxide layer 50 is formed on the semiconductor substrate 30 for covering each basic component mentioned above by utilizing the manner of chemical vapor deposition (CVD). A patterned photoresist 52 is formed on the surface of the thin oxide layer 50 on the semiconductor substrate 30 by utilizing photolithography manufacturing process, as shown in FIG. 5(c), for covering on the ESD protection component region to expose the thin oxide layer 50 on the internal circuit region 34. With the patterned photoresist 52 as a mask for carrying out wet etching to said thin oxide layer 50, the thin oxide layer 50 is removed on the internal circuit region 34 within the semiconductor substrate 30, and said unremoved thin oxide layer 50 only covers on ESD protection components region 32 of the semiconductor substrate 30. Then etching is performed for removing said photoresist 52.

After completing manufacturing of the thin oxide layer on the ESD protection components region 32, a manufacturing process is carried out on the self-aligned salicide as shown in FIG. 5(d). At first, sputtering forms a titanium metal layer 54 on the semiconductor substrate 30. The titanium metal layer 54 on the ESD protection components region 32 covers the surface of the thin oxide layer 50 and the titanium metal layer 54 within the internal circuit region 34 covers directly on the surface of poly gate 40, heavy ion doping region 46, 48, etc., components. Then a manufacturing process of high temperature rapid heating is performed. The part that the titanium metal layer 54 on the ESD protection components region 32 contacts with the surface of poly gate 40, heavy ion doping region 46, 48, etc., components generates silicification to form silicon titanium (TiSi₂), and then carries out self-alignment to form salicide 56. Salicide won't form because there is a thin oxide layer 50 to block the ESD protection components region 32.

Finally, wet etching is used to remove the titanium 54 selectively of unreacting or remnant after the reaction and remnant thin oxide layer selectively. Thus, the internal circuit region on the semiconductor substrate 30 forms to be the structure of self-aligned salicide as shown in FIG. 5(e). Therefore, the transistor structure of full deep submicron salicide manufacturing process has been completed. The material of said metal layer could be Co, Ni, Pa, Pt or other metal except titanium.

The present invention uses a block structure of the thin oxide layer on the ESD protection components region when manufacturing self-aligned salicide for avoiding undesired self-aligned salicide formed on the drain contact and poly gate within. A resistance ballast exists between the drain contact and poly gate and further renders the high current generated from electrostatic discharge capable of discharging in a homogeneous manner. Thus, the present invention guides out the high current generated from electrostatic high voltage effectively in order to avoid local high current and local heating effect generated near the drain and prevents the ESD protection structure from being broken for the ESD protection components capable of assuring their effect of ESD protection.

Although the present invention has been described with reference to specific exemplary embodiments, it will be evident that various modifications and changes may be made to these embodiments without departing from the broader spirit and scope of the invention.

1. A manufacturing method for an electrostatic discharge protection device for deep submicron manufacturing processing comprising:
providing a semiconductor substrate comprising forming block structures, doping wells, poly gate structures, light ion doping regions and heavy ion doping regions to be drain/source and basic components thereon;
forming a thin layer on said semiconductor substrate for covering each component mentioned above;
forming a patterned photoresist on the thin layer of the semiconductor substrate, and using the patterned photoresist as a mask, etching the thin layer for removing the thin layer on non-ESD protection component region of the semiconductor substrate, and the remnant thin layer only covering on the ESD protection components region of the semiconductor substrate, then removing the patterned photoresist;
carrying out a self-aligned salicide manufacturing process for forming self-aligned salicide on the surface of the poly gates, source/drain region on the non-ESD protection components region of the semiconductor substrate; and
removing the remnant thin layer.

2. The manufacturing method of electrostatic discharge protection device according to claim 1, wherein the block structures are shallow trench isolation structures.

3. The manufacturing method of electrostatic discharge protection device according to claim 1, wherein the doping wells comprise N-type doping wells and P-type doping wells.

4. The manufacturing method of electrostatic discharge protection device according to claim 1, wherein the heavy ion doping regions comprise N-type and P-type heavy ion doping regions.

5. The manufacturing method of electrostatic discharge protection device according to claim 1, wherein the thin layer is an oxide layer formed by chemical vapor deposition.

6. The manufacturing method of electrostatic discharge protection device according to claim 1, wherein the step of etching the thin layer utilizes wet-etching manner to remove the thin layer.

7. The manufacturing method of electrostatic discharge protection device according to claim 1, wherein the steps of forming the self-aligned salicide further comprises:
forming a metal layer on the semiconductor substrate;
carrying out high temperature heating process for the part that the metal layer on the ESD protection components region contacts with the surface of the poly gates, heavy ion doping region components generating silicification to self align for forming salicide.

8. The manufacturing method of electrostatic discharge protection device according to claim 7, wherein the materials of the metal layer are selected from the groups combined of Ti, Co, Ni, Pa and Pt, and Ti.

9. The manufacturing method of electrostatic discharge protection device according to claim 7, wherein carrying out the high temperature heating process is completed by rapid heating manufacturing process.

10. The manufacturing method of electrostatic discharge protection device according to claim 7, wherein the step of removing the unreacting metal layer utilizes wet-etching.

11. The manufacturing method of electrostatic discharge protection device according to claim 1, wherein the remnant thin layer utilizes wet-etching.
